(19) United States
(12) Patent Application Publication
(10) Pub. No.: US 2013/0020721 A1
(43) Pub. Date: Jan. 24, 2013

(54) SEMICONDUCTOR DEVICE AND METHOD FOR MANUFACTURING THE SAME

(71) Applicants: Yutaka NAKAE, Tokyo (JP); Nobuyuki NAKAMURA, Tokyo (JP); Tomohiko INOKUCHI, Tokyo (JP); Hidenori YAMAGUCHI, Tokyo (JP)

(72) Inventors: Yutaka NAKAE, Tokyo (JP); Nobuyuki NAKAMURA, Tokyo (JP); Tomohiko INOKUCHI, Tokyo (JP); Hidenori YAMAGUCHI, Tokyo (JP)

(73) Assignee: ELPIDA MEMORY, INC., Tokyo (JP)

(21) Appl. No.: 13/549,789

(22) Filed: Jul. 16, 2012

(30) Foreign Application Priority Data
Jul. 21, 2011 (JP) 2011-160045

(51) Int. Cl. H01L 23/48; H01L 21/768

(52) U.S. Cl. 257/774; 438/430; 257/E23.011; 257/E21.597

(57) ABSTRACT

A semiconductor device includes a semiconductor substrate, a through silicon via that penetrates through the semiconductor substrate in a thickness direction thereof, a first insulating region, a second insulating region formed below the first principal surface of the semiconductor substrate, and an isolation region made of an insulating material buried in a second trench formed below the first principal surface of the semiconductor substrate. The first insulating region is made of an insulating material buried in a first groove that surrounds the through silicon via and penetrates through the semiconductor substrate from a first principal surface thereof to a second principal surface thereof. The second insulating region is deeper than the second trench and shallower than the first trench.

This application is based upon and claims the benefit of priority from Japanese Patent Application No. 2011-160045 filed on Jul. 21, 2011, the disclosure of which is incorporated herein in its entirety by reference.

### BACKGROUND OF THE INVENTION

1. Field of the Invention

The present invention relates to a semiconductor device and a method for manufacturing the same.

2. Description of the Related Art

In a semiconductor device having high functionality achieved by stacking a plurality of semiconductor chips, the vertically stacked semiconductor chips are electrically connected to each other with through silicon vias (TSVs) penetrating through the semiconductor chips. A semiconductor chip of this type has an insulating ring structure in which an insulator surrounds each of the TSVs in order to electrically isolate the TSVs from an element region and reduce the capacitance between adjacent TSVs.

JP2009-111061 A1 discloses a method for manufacturing a semiconductor device including a through silicon via with an insulating ring. JP2009-111061 A1 specifically discloses the steps of forming an insulating ring first (via first), forming elements, wirings, and other elements, and finally forming a TSV (via last). More specifically, a ring-shaped trench extending from an element formation side of a silicon substrate in the depth direction thereof is first formed, and an insulating ring is formed by burying an insulating film in the trench. After the following steps of forming elements on the front surface of the substrate, forming a wiring layer, and forming a front-surface electrode, the rear surface of the silicon substrate is ground to reduce the thickness of the silicon substrate. In this process, the rear surface of the substrate is ground until the bottom of the insulating ring is exposed through the rear surface, thereby forming a structure in which the insulating ring penetrates through the silicon substrate from the front surface to the rear surface thereof. A TSV is then completed by forming a rear-surface electrode in the insulating ring from the rear surface through the silicon substrate.

### SUMMARY OF THE INVENTION

In one embodiment, there is provided a semiconductor device, comprising:

a semiconductor substrate;

a through silicon via penetrating through the semiconductor substrate in a thickness direction thereof;

a first insulating region made of an insulating material buried in a first trench, the first trench surrounding the through silicon via and penetrating through the semiconductor substrate from a first principal surface thereof to a second principal surface thereof;

a second insulating region formed below the first principal surface of the semiconductor substrate; and

an isolation region made of an insulating material buried in a second trench formed below the first principal surface of the semiconductor substrate,

wherein the second insulating region is deeper than the second trench and shallower than the first trench.

In another embodiment, there is provided method for manufacturing a semiconductor device, comprising:

forming a first trench surrounding a part of a semiconductor substrate and a trench for a second insulating region, below a first principal surface of the semiconductor substrate;

burying an insulating material in the first trench and the trench for the second insulating region, to form a first insulating region and the second insulating region, respectively;

forming a photoresist film on the first principal surface of the semiconductor substrate, after burying the insulating material;

transferring a first pattern aligned with reference to the second insulating region to the photoresist film;

etching the semiconductor substrate using the photoresist film as a mask to form a second trench, after transferring the first pattern to the photoresist film;

burying an insulating material in the second trench, to form an isolation region;

grinding a second principal surface of the semiconductor substrate until the first insulating region is exposed; and

forming a through silicon via penetrating through the part of the semiconductor substrate surrounded by the first trench from the first principal surface thereof to the second principal surface thereof,

wherein the second insulating region is deeper than the second trench and shallower than the first trench.

### BRIEF DESCRIPTION OF THE DRAWINGS

The above features and advantages of the present invention will be more apparent from the following description of certain preferred embodiments taken in conjunction with the accompanying drawings, in which:

FIGS. 1A to 1C show a method studied by the present inventors;

FIGS. 2A to 2D show the method studied by the present inventors;

FIGS. 3A to 3E show the method studied by the present inventors;

FIGS. 4A to 4C show a method for manufacturing a semiconductor device according to a first exemplary embodiment;

FIGS. 5A to 5C show the method for manufacturing a semiconductor device according to the first exemplary embodiment;

FIG. 6 is a flowchart showing the method for manufacturing a semiconductor device according to the first exemplary embodiment;

FIGS. 7A to 7D show the method for manufacturing a semiconductor device according to the first exemplary embodiment;

FIGS. 8A to 8D show the method for manufacturing a semiconductor device according to the first exemplary embodiment;

FIGS. 9A to 9D show the method for manufacturing a semiconductor device according to the first exemplary embodiment;

FIGS. 10A to 10D show the method for manufacturing a semiconductor device according to the first exemplary embodiment;

FIGS. 11A to 11D show the method for manufacturing a semiconductor device according to the first exemplary embodiment;

FIGS. 12A to 12D show the method for manufacturing a semiconductor device according to the first exemplary embodiment;

FIGS. 13A to 13D show the method for manufacturing a semiconductor device according to the first exemplary embodiment;

FIGS. 14A to 14D show the method for manufacturing a semiconductor device according to the first exemplary embodiment;

FIGS. 15A and 15B show the method for manufacturing a semiconductor device according to the first exemplary embodiment;

FIGS. 16A and 16B show the method for manufacturing a semiconductor device according to the first exemplary embodiment;

FIGS. 17A and 17B show the method for manufacturing a semiconductor device according to the first exemplary embodiment; and

FIG. 18 shows the method for manufacturing a semiconductor device according to the first exemplary embodiment.

FIGS. 19A to 19D show a method for manufacturing a semiconductor device according to a second exemplary embodiment;

FIGS. 20A and 20D show the method for manufacturing a semiconductor device according to the second exemplary embodiment;

FIGS. 21A and 21D show the method for manufacturing a semiconductor device according to the second exemplary embodiment;

In the drawings, numerals have the following meanings: 1: alignment mark, 2: scribe region, 3: chip region, 4: element region, 5: through silicon via, 6: insulating ring, 7: isolation region (STI), 8: element, 8a: wiring layer, 8b: contact plug, 9, 12: solder film, 10, 11: seed film, 13, 19: copper bump, 14: wiring layer, 16: interlayer insulating film, 17: semiconductor substrate, 20: silicon oxide film, 21, 21a, 21b, 23, 27: photoresist film, 22, 22a, 22b,: pattern for alignment mark, 24: pattern for insulating ring, 25: trenches for alignment mark, 26 NSG (none-doped silicate glass) film, 28: silicon nitride film, 29: first pattern, 32: trench for insulating ring, 33: first principal surface, 34: second principal surface, 36: coating film, 40: semiconductor chip, 41: underfill material, 42: package substrate, 43: mold resin

### DETAILED DESCRIPTION OF THE PREFERRED EMBODIMENTS

JP2005-217071 A1 discloses a method in which an alignment mark that serving as a reference for alignment when chips are stacked on each other, is simultaneously formed in the step of forming TSV bodies. More specifically, in the technology disclosed in JP2005-217071 A1, there is formed the alignment mark for allowing a bonding apparatus to recognize the position of a chip so that a plurality of chips cut from a wafer are stacked on each other without misalignment. The alignment mark is made of the same conductive material as that of the TSVs that penetrates through the substrate and formed simultaneously with the TSVs.

As an application of the technology described above, the present inventors studied in advance a method for forming an insulating ring simultaneously with an alignment mark serving as a reference for alignment in the step of transferring an STI (field) pattern (photolithography step), which is a first step of an element formation procedure. In general, when an STI region is first formed on a wafer on which no component of a semiconductor device is formed, STI region needs not to be aligned with any element. Accordingly, no alignment mark is required in the STI formation step. In the steps following the STI formation step, an element may be aligned based on the alignment mark formed simultaneously in the STI formation step. On the other hand, a structure to which the present application is directed experiences an element formation step after first forming insulating rings that surround TSVs (via first). It is therefore necessary to provide an alignment mark (field registration mark) for aligning the STI region with the insulating rings, and the present inventors studied the technology described above as a method for forming the alignment mark. The field registering mark studied by the present inventors has a shape in which insulating trenches are arranged in lines and spaces (L/S) so that they are recognized in a lithography step.

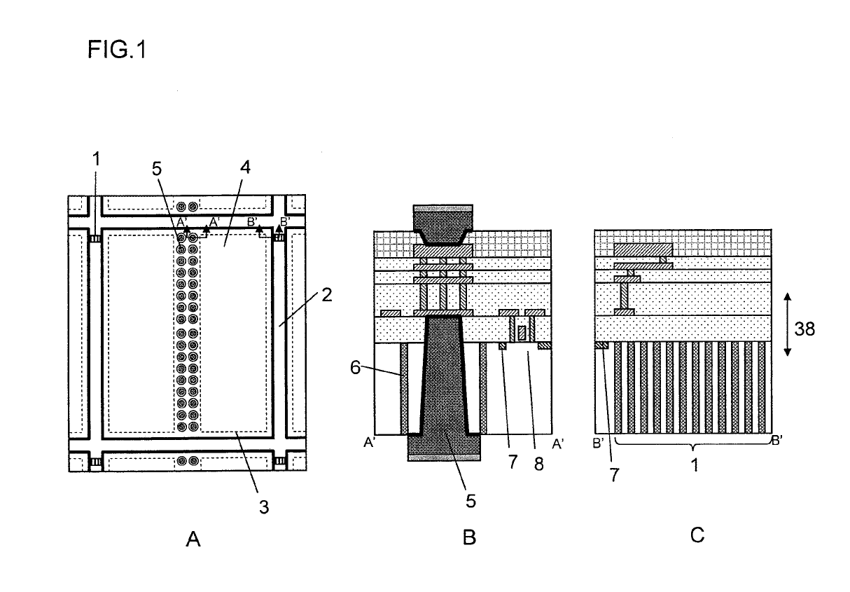

A semiconductor device and a method for manufacturing the same studied by the present inventors will be described with reference to FIGS. 1 to 3. As shown in FIG. 1A, the semiconductor device includes scribe region 2 and chip region 3 surrounded by scribe region 2 on a substrate. Element region 4 and through silicon vias 5 are provided in chip region 3, and alignment marks 1 are provided in scribe region 2. FIG. 1B is a cross-sectional view of a portion in the vicinity of one of the through silicon vias in FIG. 1A taken along a plane including the direction A-A, and FIG. 1C is a cross-sectional view of a portion in the vicinity of the alignment mark in FIG. 1A taken along a plane including the direction B-B. As shown in FIG. 1B, respective annular insulating rings 6 that surround respective through silicon vias 5 are provided in element region 4 so that through electrodes 5. The through silicon via 5 is electrically isolated from other elements by the insulating ring 6. As shown in FIG. 1C, alignment mark 1 is disposed in scribe region 2, as shown in FIG. 1C. Insulating rings 6 and alignment mark 1 have the same length in substrate thickness direction 38. Isolation region (STI) 7 is provided in each of element region 4 and scribe region 2.

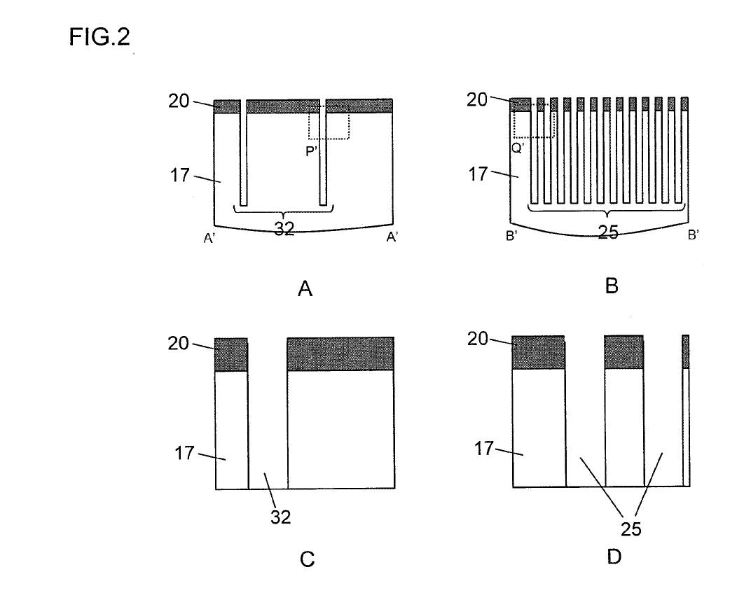

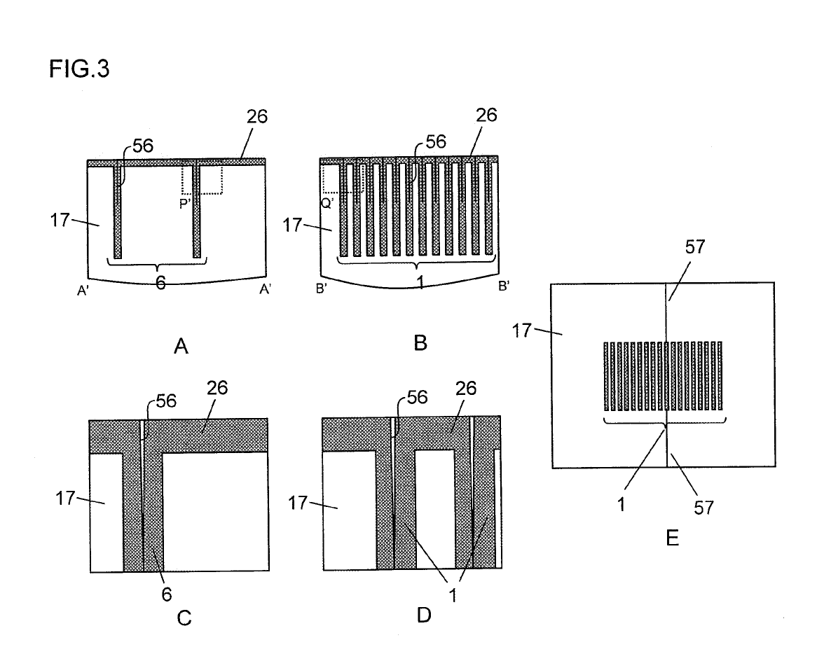

FIGS. 2 to 3 show the steps of forming the insulating rings and the alignment mark in the semiconductor device shown in FIG. 1 but do not show the other portions for ease of description. FIGS. 2A and 3A show the step of forming the insulating rings in FIG. 1B. FIGS. 2B and 3B show the step of forming the alignment mark in FIG. 1C. FIGS. 2C and 3C are enlarged views of portion P′ enclosed with the dotted line in FIGS. 2A and 3A. FIGS. 2D and 3D are enlarged views of portion Q′ enclosed with the dotted line.

As shown in FIG. 2, the front surface of a silicon semiconductor substrate is thermally oxidized to form silicon oxide film 20. A photoresist film (not shown) is formed on silicon oxide film 20 and is then patterned by using a lithography technique. The patterned photoresist film is subsequently used as a mask to pattern silicon oxide film 20. Patterned silicon oxide film 20 is used to dry etch the semiconductor substrate. In the dry etching process, annular trench (trench for insulating ring) 32 and trenches 25 for the alignment mark are simultaneously formed. Trenches 25 for the alignment mark are formed so that they have a line-and-space (L/S) shape including a plurality of trenches arranged at fixed intervals in the width direction of scribe region 2 when viewed in the direction toward a first principal surface.

As shown in FIG. 3, after the photoresist film and silicon oxide film 20 are removed, insulating film 26 is buried in the two types of trenches simultaneously. In this process, an NSG (none-doped silicate glass) film formed by a CVD (chemical vapor deposition) process using TEOS (Tetra EthOxy Silane: Si(OC₂H₅)₄) as a raw material is buried in the trenches. Insulating rings 6 and alignment mark 1 are thus formed.

The trenches for the alignment mark 25 formed in the same manner as the trench for the insulating ring have a deep depth (about 40 μm or less) and a narrow width (about 2 μm or less). Accordingly, the insulating material is defectively buried in the trenches 25, and a seam or void 56 is easy to be formed. In particular, a study performed by the present inventors shows that in an alignment mark including a plurality of trenches arranged in the form of L/S, stress concentration occurs in a defectively buried portion, resulting in crack 57 in the substrate. Crack 57 sometimes reaches the element region, resulting in decrease in manufacturing yield. It was therefore found that the manufacturing method studied by the present inventors was yet to be improved.

In view of the fact described above, the present inventors studied a method for preventing the crack described above from occurring. As a result, the present inventors found that the crack does not occur when the trenches for the alignment mark were formed to be shallower than the trench for the insulating ring and deeper than the trench for STI. That is, in a method for manufacturing a semiconductor device according to the present invention, the trenches for the alignment mark are formed to be shallow. Accordingly, seam, void, or other defectively buried portion does not occur when an insulating film is buried in the trenches. As a result, occurrence of crack is prevented, to improve manufacturing yield.

The invention will be now described herein with reference to illustrative embodiments. Those skilled in the art will recognize that many alternative embodiments can be accomplished using the teachings of the present invention and that the invention is not limited to the embodiments illustrated for explanatory purposes.

### First Exemplary Embodiment

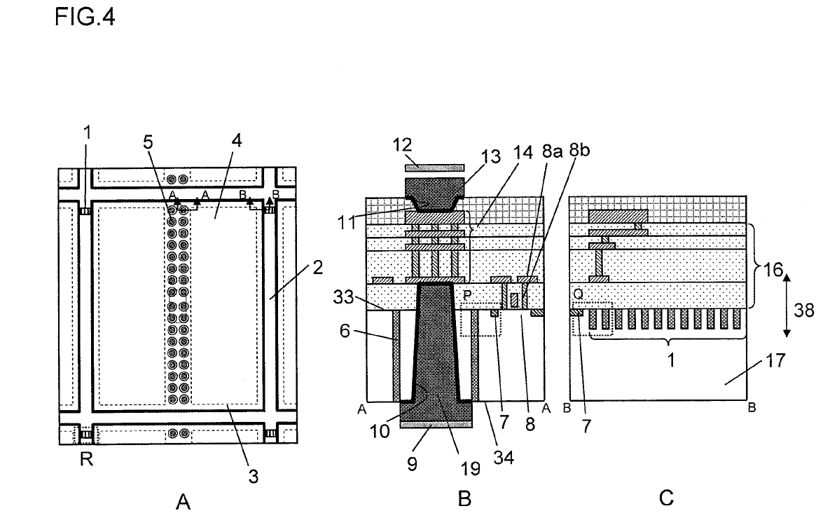

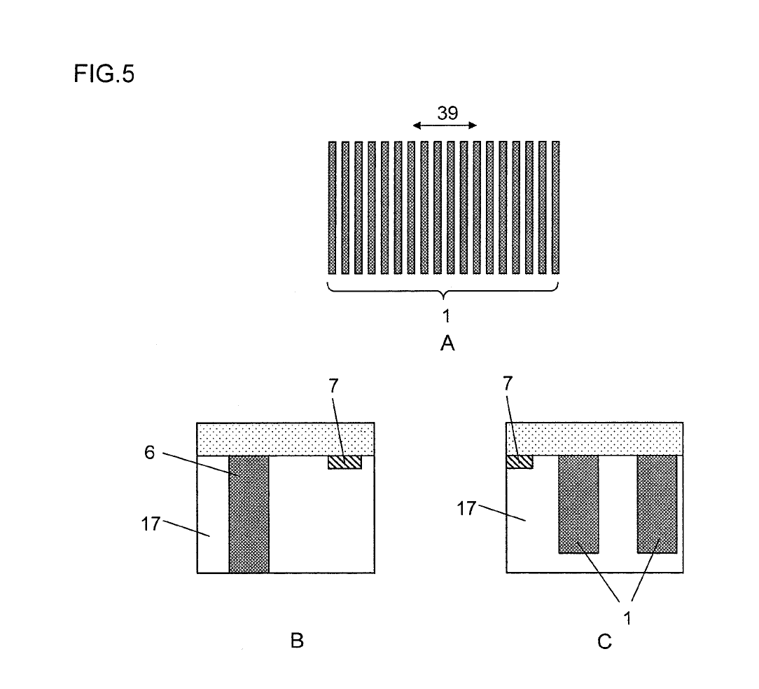

FIGS. 4 to 5 show a semiconductor device manufactured by using the manufacturing method according to the first exemplary embodiment. As shown in FIG. 4A, the semiconductor device includes scribe region (cut region) 2 on a substrate and chip region 3 surrounded by scribe region 2, as shown in FIG. 4A. Element region 4 and through silicon vias 5 are provided in chip region 3, and a plurality of semiconductor chips can be electrically connect to each other via through silicon vias 5. Alignment marks 1 are provided in scribe region 2.

FIG. 4B is a cross-sectional view of a portion in the vicinity of one of the through silicon vias taken along a plane including the direction A-A in FIG. 4A. FIG. 4C is a cross-sectional view of a portion in the vicinity of the alignment mark taken along a plane including the direction B-B in FIG. 4A. FIG. 5A is an enlarged view of portion R enclosed with the dotted line in FIG. 4A. FIG. 5B is an enlarged view of portion P enclosed with the dotted line in FIG. 4B. FIG. 5C is an enlarged view of portion Q enclosed with the dotted line in FIG. 4C.

As shown in FIG. 4B, each insulating ring 6, which has an annular shape when viewed in the direction toward the first principal surface, is provided in element region 4. Insulating ring 6 (first insulating region) 6 is made of an insulating material which is buried in a first trench extending from first principal surface 33 in the thickness direction of the semiconductor substrate and penetrating through semiconductor substrate 17 to second principal surface 34. Insulating ring 6 is provided so that it surrounds corresponding through silicon via 5 and isolates through silicon via 5 from other elements 8. As shown in FIGS. 4C and 5A, alignment mark (second insulating region) 1 is provided in scribe region 2. Alignment mark has the lines and spaces shape in which trenches are arranged at fixed intervals in the width direction of scribe region 2 when viewed in the direction toward the first principal surface. Isolation region (STI) 7 is provided in each of element region 4 and scribe region 2. As shown in FIGS. 4B, 5B and 5C, alignment mark 1 is shallower than insulating rings 6a and deeper than STI 7 in thickness direction 38 of the semiconductor substrate. In addition, a bottom surface of alignment mark 1 is positioned closer to the first principal surface 33 than to the second principal surface 34.

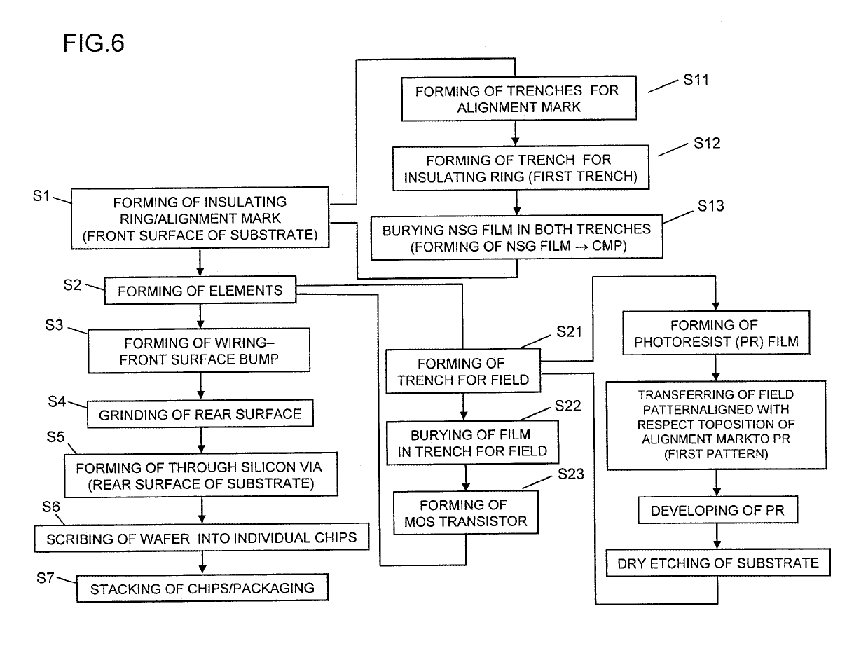

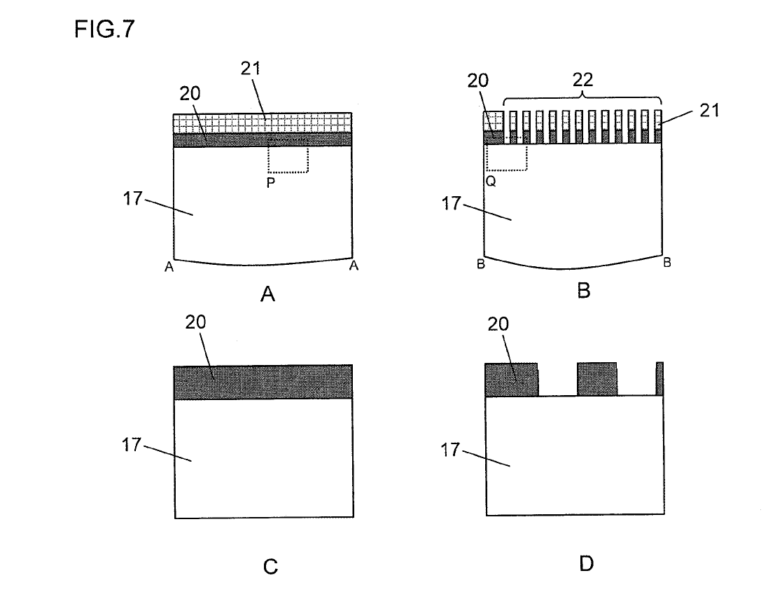

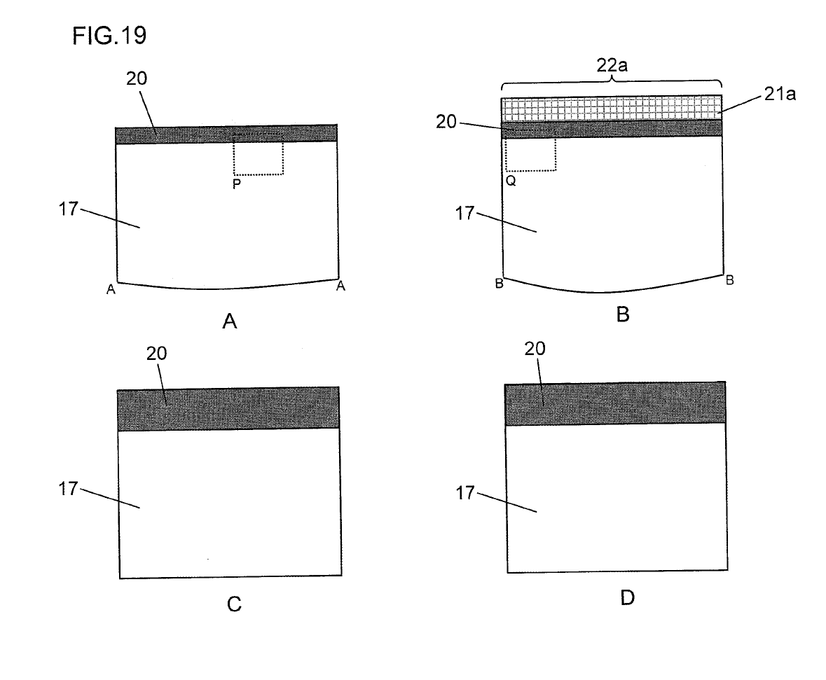

FIGS. 6 to 18 describe a method for manufacturing the semiconductor device according to the exemplary embodiment. The manufacturing method according to the exemplary embodiment will be described below with reference FIGS. 6 to 18. FIG. 6 is a flowchart showing the manufacturing method according to the exemplary embodiment. In FIGS. 7 to 17, FIGS. 7A to 17A are cross-sectional views corresponding to FIG. 4B, FIGS. 7B to 17B are cross-sectional views corresponding to FIG. 4C, FIGS. 7C to 14C are cross-sectional views corresponding to FIG. 5B, and FIGS. 7D to 14D are cross-sectional views corresponding to FIG. 5C. The same applies to FIGS. 19 to 21 of a second exemplary embodiment.

As shown in FIG. 7, the front surface of silicon semiconductor substrate 17 is thermally oxidized to form silicon oxide film (protective film) 20, and photoresist film 21 is formed on silicon oxide film 20, as shown in FIG. 7A. Pattern 22 for the alignment mark is formed in photoresist film 21 by using a lithography technique. Silicon oxide film 20 is dry etched by using pattern 22, to transfer pattern 22 to silicon oxide film 20. The patterned silicon oxide film 20 constitutes first protective pattern.

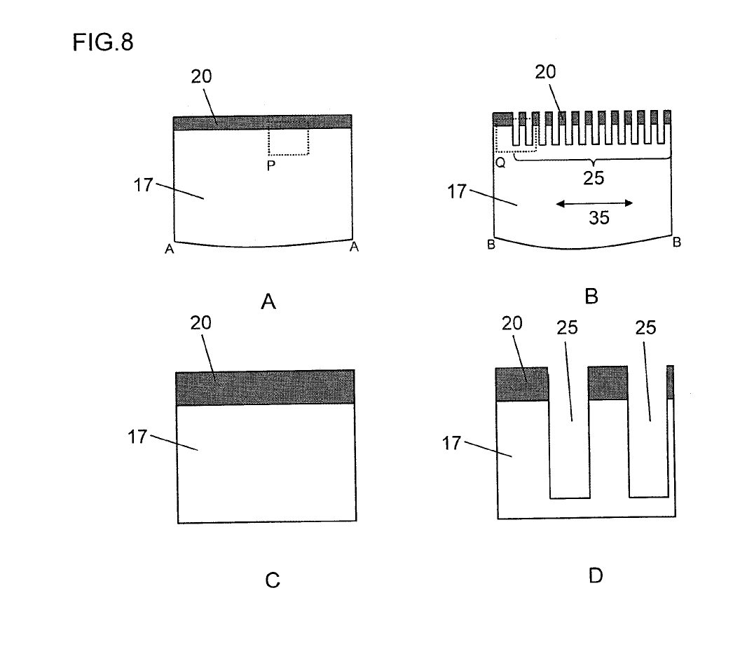

As shown in FIG. 8, semiconductor substrate 17 is etched by using silicon oxide film 20 to which pattern 22 has been transferred, thereby forming trenches 25 for the alignment mark having a depth of 0.5 μm, a width of 2 μm, an interval of 4 μm, and a length of 42 μm in width direction 35 of the scribe region (S11 in FIG. 6). Dimensions of trenches 25 for the alignment mark are not necessarily limited to specific dimensions but may have any dimensions as long as they are shallower (shorter in thickness direction 38 of the semiconductor substrate) than the trench for the insulating ring (first trench) to be formed later. To bury a film in trenches 25 for the alignment mark in a manner satisfactory enough to prevent any crack from occurring, the depth of trenches 25 for the alignment mark from the first principal surface is preferably 2 μm or smaller. On the other hand, to correctly recognize the alignment mark in a photolithography process in the following step of forming a field pattern for STI, the depth of trenches 25 for the alignment mark from the first principal surface is preferably 0.1 μm or greater. It is further preferable that the width of trenches 25 for the alignment mark ranges from 1 to 3 μm, the interval therebetween ranges from 2 to 6 μm, and the length thereof in width direction 35 ranges from 30 to 50 μm. Sizing trenches 25 for the alignment mark within the ranges described above effectively prevents defects in burying the insulating material in the trenches 25. Photoresist film 21 is then removed.

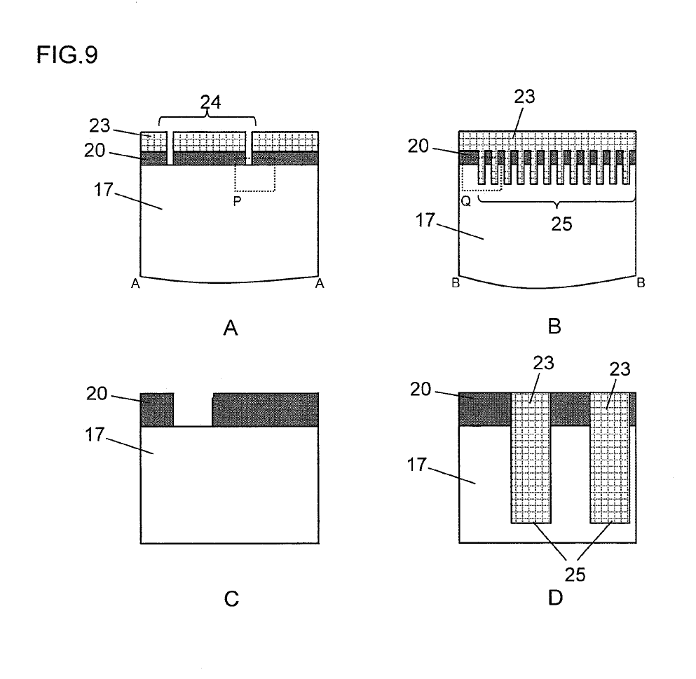

As shown in FIG. 9, photoresist film 23 is formed on silicon oxide film 20, and then pattern 24 for the insulating ring is formed in photoresist film 23 by using a lithography technique. Silicon oxide film 20 is dry etched by using pattern 24 to transfer pattern 24 to silicon oxide film 20. The patterned silicon oxide film 20 constitutes second protective pattern.

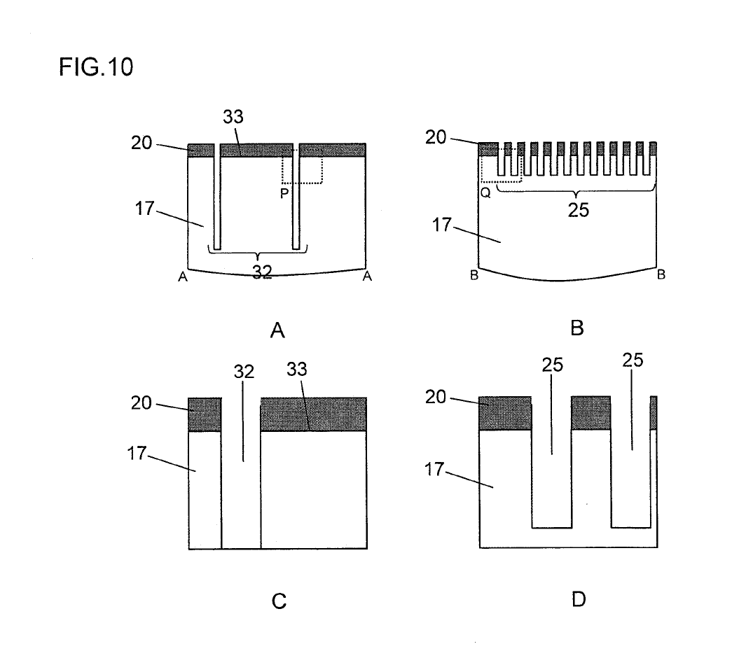

As shown in FIG. 10, semiconductor substrate 17 at the side of first principal surface 33 is etched by using silicon oxide film 20 to which pattern 24 has been transferred. Trench 32 (first trench) for the insulating ring having a depth of 40 μm, a width of 2 μm, and a ring diameter of 20 μm is thus formed (S12 in FIG. 6). Dimensions of trench 32 for the insulating ring are not necessarily to specific dimensions but may have any dimensions as long as trench 32 are deeper (longer in thickness direction 38 of the semiconductor substrate) than trenches 25 for the alignment mark. For example, trench 32 for the insulating ring can have a depth ranging from 30 to 50 μm, a width ranging from 1 to 3 μm, and a ring diameter ranging from 15 to 30 μm. Photoresist film 23 is then removed.

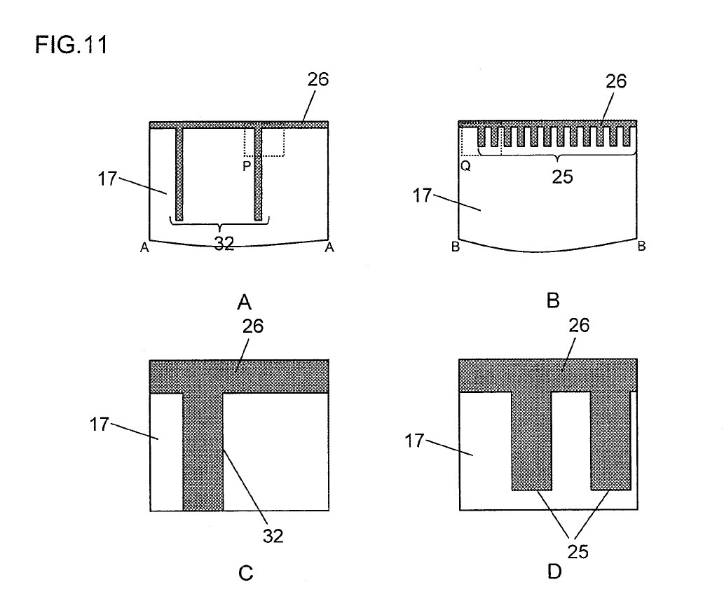

As shown in FIG. 11, silicon oxide film 20 is removed. NSG (none-doped silicate glass) film 26 is formed on the semiconductor substrate 17 by a CVD process using TEOS (Tetra EthOxy Silane: Si(OC₂H₅)₄) as a raw material, and then degassing is performed by heat treating the resultant structure at 950° C. for 60 minutes. In this process, trench 32 for the insulating ring and trenches 25 for the alignment mark are also buried with NSG film 26 (S13 in FIG. 6). As the inventors study in the above description, when the trenches for the alignment mark and the trench for the insulating ring are formed so that they have the same depth, the NSG film is not buried in the trenches for the alignment mark in a satisfactory manner. As a result, seams and voids occur in the NSG film buried in the trenches for the alignment mark. In particular, when the trenches for the alignment mark formed have a shape in which a plurality of trenches are arranged in the form of L/S, stress concentration tends to occur in a defectively buried portion, resulting in a crack in the substrate. The crack, when it reaches the element region, contributes to decrease in manufacturing yield. In contrast, trenches 25 for the alignment mark are formed so as to be shallower than trench 32 for the insulating ring in the exemplary embodiment. As a result, NSG film 26 is buried in trenches 25 for the alignment mark in a satisfactory manner, thereby reducing the occurrence of seams, voids, and other defectively buried portions. It is possible to prevent stress concentration from occurring in a defectively buried portion due to the line-and-space repeated pattern of the alignment mark, and hence the occurrence of cracking in the present step can be reduced. As a result, the manufacturing yield can be improved.

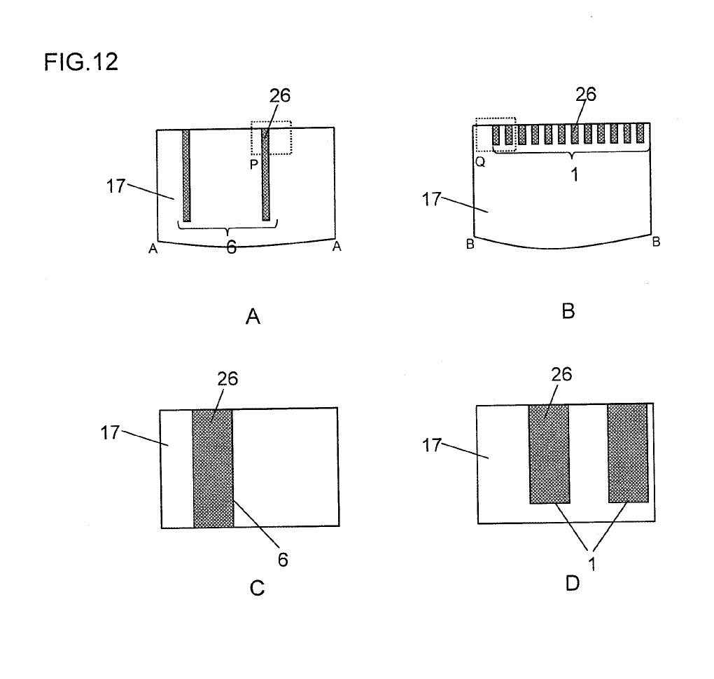

As shown in FIG. 12, the semiconductor substrate is used as a stopper to perform CMP on NSG film 26. Insulating ring (first insulating region) 6 and alignment mark (second insulating region) 1 are thus formed. To reduce the amount of CMP, the CMP may be performed after the thickness of the NSG film on the front surface of the substrate is reduced by a wet etching process. Further, in the wet etching process, the upper surfaces of insulating ring 6 and alignment mark 1 may be covered with a photoresist film. Seams have possibilities of occurring in insulating ring 6 or alignment mark 1. Photoresist film can prevent seams from deepening due to the wet etching process.

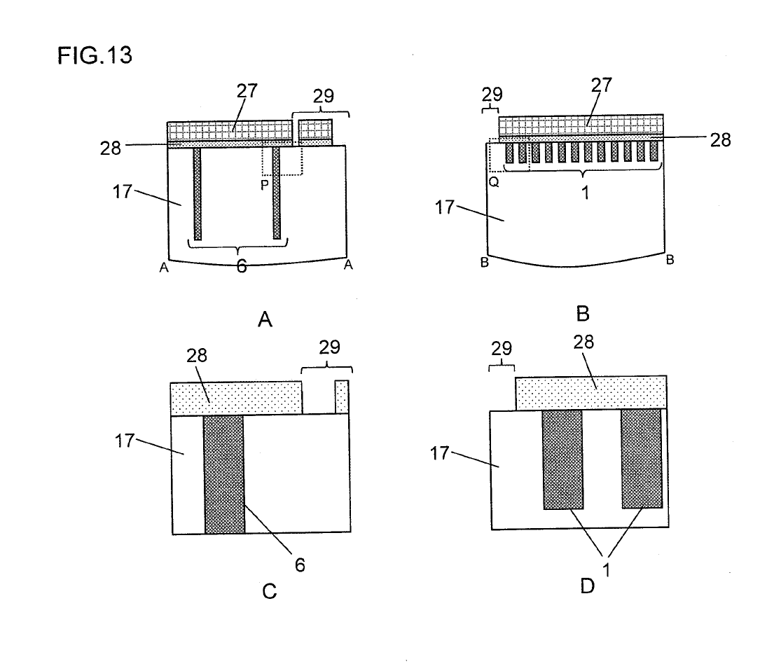

As shown in FIG. 13, silicon nitride film 28 is formed on the semiconductor substrate, and then photoresist film 27 is further formed. A field pattern for STI is transferred to photoresist film 27 to form first pattern 29 by using a lithography technique. In this process, alignment mark 1 formed as described above can be used in the exemplary embodiment as a mark for aligning the field pattern for STI. That is, the field pattern aligned with respect to the position of alignment mark 1 described above on the substrate is transferred to photoresist film 27, thereby reducing the misalignment in the photolithography process. First pattern 29 in the photoresist film is used to dry etch silicon nitride film 28, thereby transferring first pattern 29 to silicon nitride film 28.

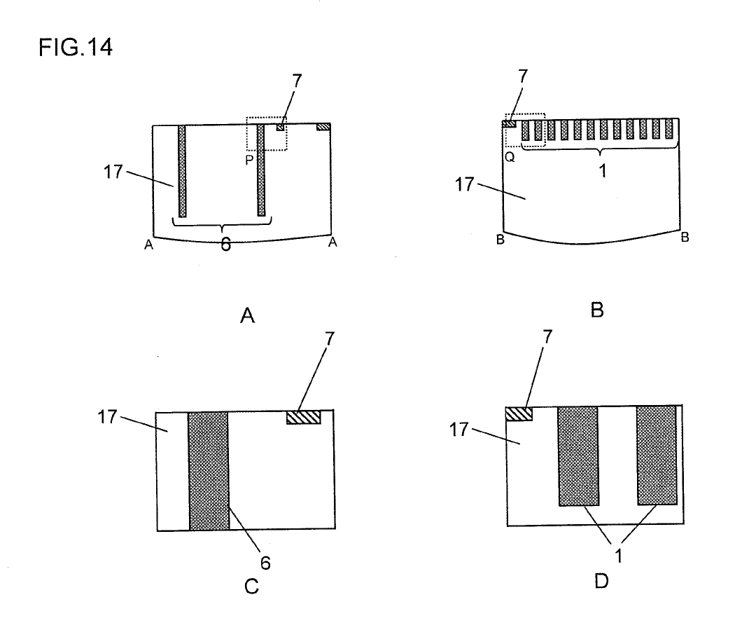

As shown in FIG. 14, semiconductor substrate 17 is etched by using silicon nitride film 28 to which first pattern 29 has been transferred, thereby forming trench for STI (second trench) (S21 shown in FIG. 6). In this time, trench for STI is formed so that the trenches for the alignment mark are deeper than trench for STI. Photoresist film 27 is then removed. After an insulating film, such as a silicon oxide film or a silicon nitride film, is buried in the semiconductor substrate 17, silicon nitride film 28 is then used as a stopper to perform CMP on the insulating film. Silicon nitride film 28 is then removed to form STI region (isolation region) 7 (S22 in FIG. 6).

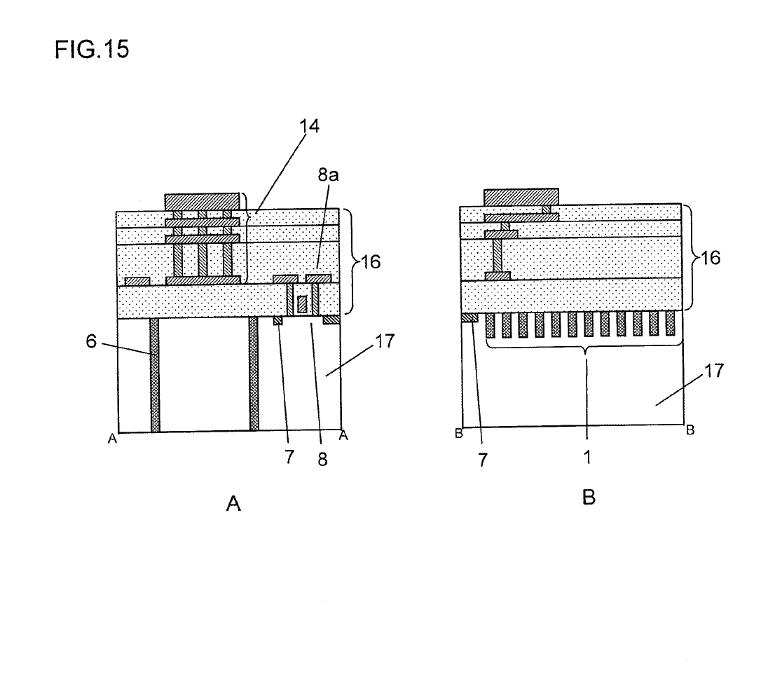

As shown in FIG. 15, element 8 such as transistor is formed in the active region of the semiconductor substrate 17 (S23 in FIG. 6), as shown in FIGS. 15A and 15B. Interlayer insulating films 16 are formed on the semiconductor substrate 17 by carrying out several film formation steps. In the middle of the step of forming interlayer insulating films 16, there are formed contact plugs 8b that reach impurity diffusion layers in transistor 8, wiring layers 8a, and wiring layer 14 above a region of the semiconductor substrate 17 that is surrounded by each insulating ring. Wiring layer 14 functions as a pad for connecting the transistor 8 to a plug of a through silicon via to be formed in the following step. Wiring layer 14 includes a plurality of wirings made of aluminum (Al) or copper (Cu), and a plurality of contact plugs which connect a plurality of wirings and made of a metal film such as tungsten.

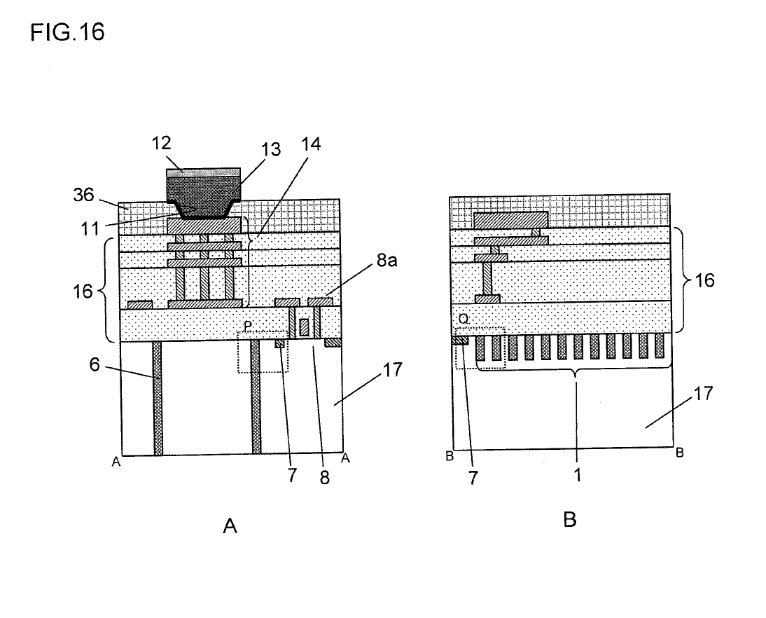

As shown in FIG. 16, coating film 36 such as silicon oxynitride film (SiON) is formed on interlayer insulating films 16 that coating film 36 covers wiring layer 14. First opening is then formed in coating film 36 so that the upper surface of wiring layer 14 is exposed. Seed film 11 is formed on coating film 36 including the first opening by a sputtering process. A photoresist film (not shown) is formed over coating film 36 and then is patterned to expose seed film 11 in the first opening. Copper bump 13 and solder film 12 are sequentially formed on exposed seed film 11 by an electrolytic plating process. After the photoresist film on coating film 36 is removed, exposed seed film 11 is removed. A set of seed film 11, copper bump 13, and solder film 12 forms a front-surface electrode (S3 in FIG. 6).

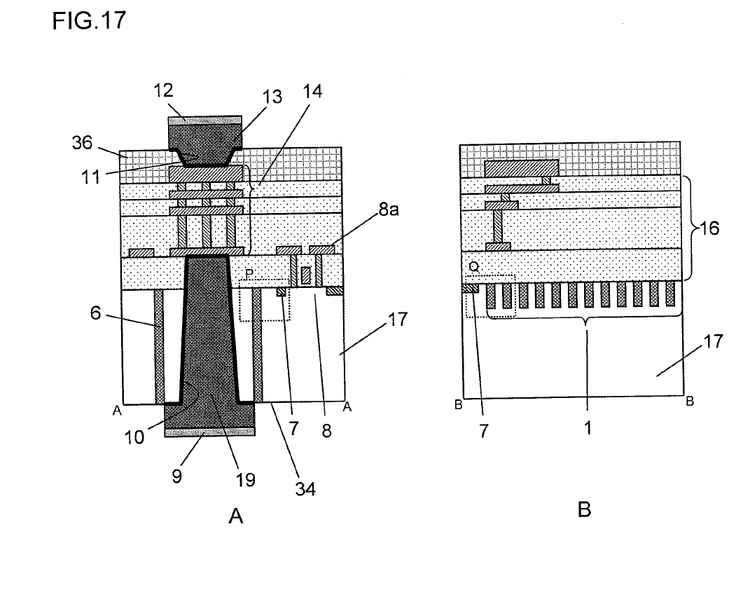

As shown in FIG. 17, a support substrate (not shown) is provided via an adhesive layer (not shown) on the side of the semiconductor substrate 17 where the front-surface electrodes have been provided. A second principal surface of semiconductor substrate 17 that faces away from first principal surface 33 in the thickness direction is then thinned, for example, from a thickness of 775 μm to a thickness ranging from 40 to 50 μm (S4 in FIG. 6). In the grounding step, the bottom of first formed insulating ring 6 is exposed on the side of second principal surface 34 of the semiconductor substrate 17. Anisotropic dry etching is performed on semiconductor substrate 17 positioned inside annular insulating ring 6, from the side of second principal surface 34 of the semiconductor substrate 17, which faces away from the first principal surface 33 in the thickness direction. In this process, wiring layer 14 is exposed, and there is formed second opening that penetrates through semiconductor substrate 17 and extends to part of interlayer insulating films 16. A titanium (Ti) film and a copper (Cu) film are then stacked all over second principal surface 34 of semiconductor substrate 17 by a sputtering process to form seed film 10. A photoresist pattern (not shown) including third opening located in the same position as that of the second opening is formed on the second principal surface 34 of semiconductor substrate 17. Copper bump 19 and solder film 9, such as an SnAg film, are sequentially formed in each of the third opening by an electrolytic plating process (S5 in FIG. 6). A set of the three layers, seed film 10, copper bump 19, and solder film 9, forms a rear-surface electrode. After the photoresist pattern is removed, exposed seed film 10 is removed.

The surface of solder film 9 is then made convex by a reflow process. The adhesive layer and the support substrate are removed. The semiconductor device shown in FIGS. 4 to 5 is thus obtained. In the semiconductor device, through silicon vias 5 that penetrate through semiconductor substrate 17 are provided in each of chip regions 3 partitioned by scribe regions 2. Upper and lower ends of each through silicon via 5 include bumps for connecting (protruding electrodes). A plurality of vertically arranged semiconductor chips are electrically connected to each other via through silicon vias 5 when they are stacked on each other. Each through silicon via 5 include through plugs (front-surface electrode and rear-surface electrode) that penetrate through semiconductor substrate 17 and wiring layer 14 that penetrates through the plurality of interlayer insulating films 16 formed on semiconductor substrate 17. The portion of each through electrode 5 that penetrates through semiconductor substrate 17 is surrounded by annular insulating ring 6 and the portion is electrically isolated from the other elements.

Semiconductor substrate 17 is then scribed along scribe regions (cut regions) 2 (S6 in FIG. 6). Semiconductor substrate 17 is thus divided into individual semiconductor chips.

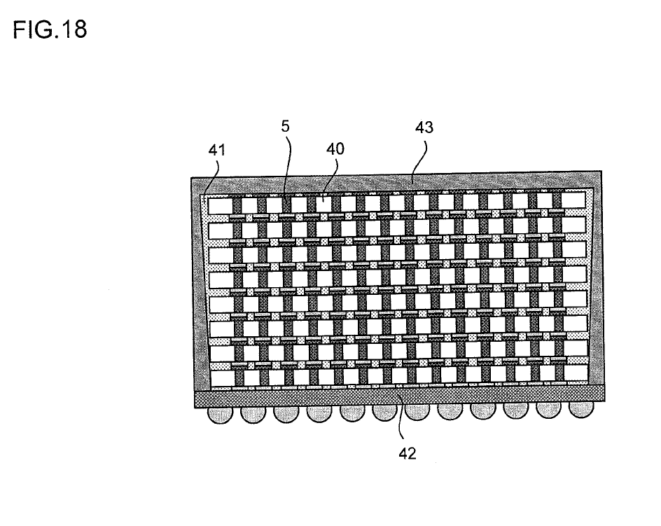

As shown in FIG. 18, a plurality of semiconductor chips 40 are mounted so that the front-surface electrode and the rear-surface electrode of different semiconductor chips come into contact with each other. The solder film of the front-surface electrode and the solder film of the rear-surface electrode are bonded to each other by a reflow process. The spaces between semiconductor chips 40 are filled with underfill material 41, and then the plurality of connected semiconductor chips 40 are mounted on package substrate 42. After that, the entire structure is molded by using mold resin 43. The semiconductor device according to the exemplary embodiment is thus completed (S7 in FIG. 6).

Examples of the semiconductor device according to the exemplary embodiment may include a DRAM, an SRAM, a flash memory, and other storage devices, an MPU, a DSP, and other arithmetic processing unit.

In the exemplary embodiment, the trenches for the alignment mark are first formed and then the trench for the insulating ring is formed, but the two types of trenches are not necessarily formed in this order. That is, to provide the advantageous effects described above, the trenches for the alignment mark and the trench for the insulating ring need to be formed so that the trenches for the alignment mark is shallower than the trench for the insulating ring. It is possible to provide the advantageous effects of the present invention, irrespective of the order in which the two types of trenches are formed. On the other hand, in consideration of removability of a photoresist film used to form each type of trench, it is preferable that the trenches for the alignment mark are first formed, as the exemplary embodiment. That is, as shown in FIG. 12, photoresist used to pattern the trench to be formed later invades in the firstly formed first trench. To remove photoresist in the firstly formed first trench effectively, it is preferable to first form the trenches for the alignment mark having a shallow depth.

Further, in the exemplary embodiment, an NSG film formed by a CVD process using TEOS as a raw material is used by way of example of an insulating film buried in the trenches, but the material buried in the trenches is not limited thereto. When an insulating film is buried in a deep, wide trench, such as a trench for an insulating ring, a defectively buried portion is easy to occur even when an NSG film is not used. In an alignment mark formed of such trenches arranged repeatedly in the form of lines and spaces, stress concentration and hence cracks are easy to occur in the defectively buried portion described above. The present invention is therefore not limited to an application in which an NSG film is buried but is also effective when applied to the step of burying another insulating film in a trench. On the other hand, when an NSG film is used, a heat treatment is required for degassing. In some cases, an NSG film shrinks due to the heat treatment process and hence seams enlarge. The present invention is therefore more effective when applied to the step of burying an NSG film in a trench.

### Second Exemplary Embodiment

In the first exemplary embodiment, as shown in FIGS. 7 to 10, the trenches 25 for the alignment mark and the trench 32 for the insulating ring (first trench) are formed in different processes, respectively. In contrast, the present exemplary embodiment is different from the first exemplary embodiment in that the trenches 25 for the alignment mark and the trench 32 for the insulating ring are formed in one process. The manufacturing method according to the exemplary embodiment will be described below with reference FIGS. 19 to 21, with focusing about the processes different from those of the first exemplary embodiment.

As shown in FIG. 19, silicon oxide film 20 is formed on a surface of the silicon semiconductor substrate 17. After that, negative photoresist film (first film) 21 a is formed on the silicon oxide film 20. By using lithography technology, there is formed a second pattern 22a which is made of only photoresist film 21a remaining in a region in which the trenches 25 for the alignment mark is to be formed.

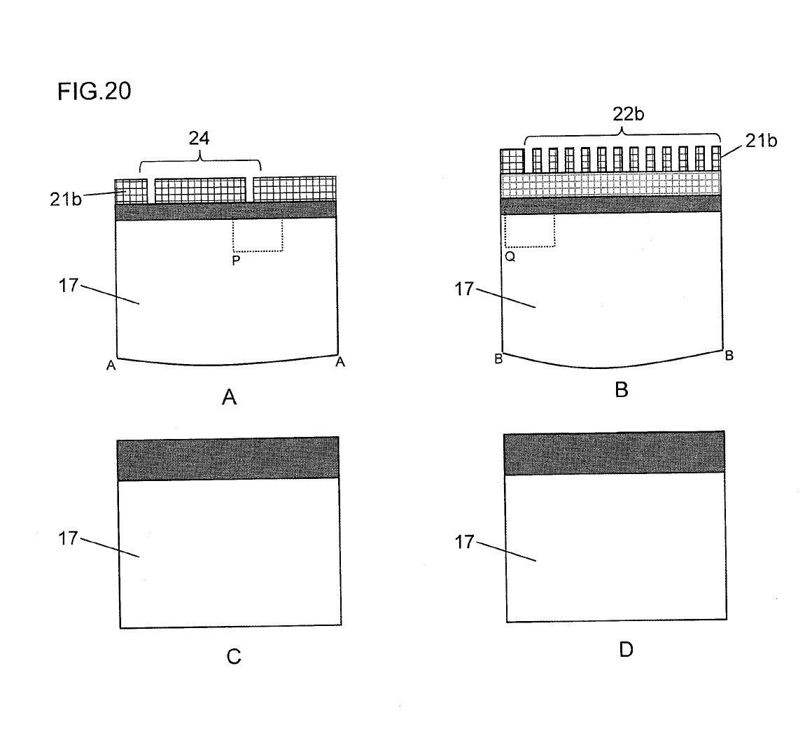

As shown in FIG. 20, positive photoresist film (second film) 21b is formed all over the silicon semiconductor substrate 17. By using the lithography technology, pattern 22b for the alignment mark and pattern 24 for the insulating ring are formed in the photoresist film 21b. The patterns 22b and 24 constitute a third pattern.

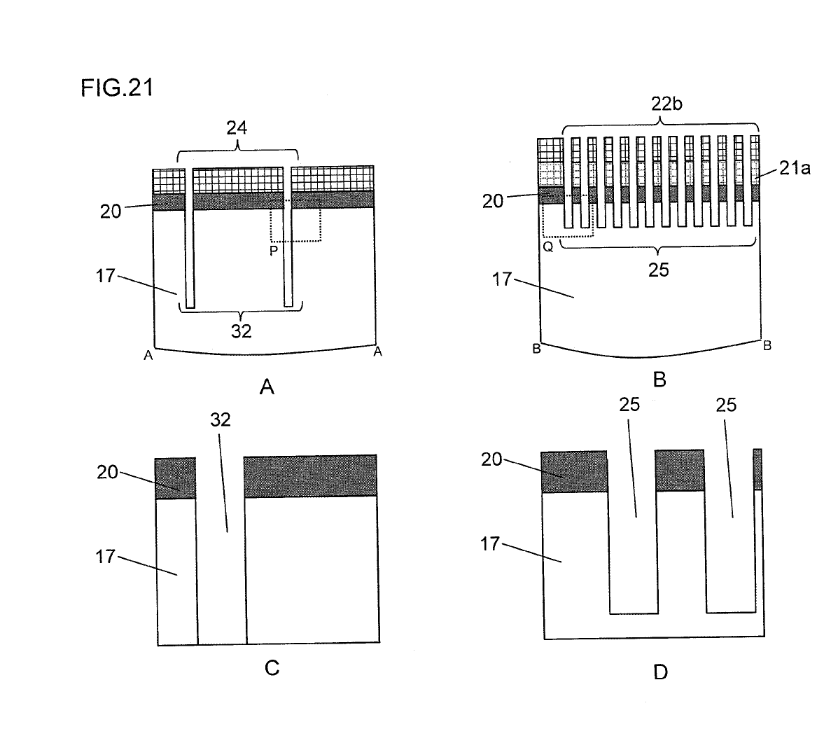

As shown in FIG. 21, the trenches 25 for the alignment mark and the trench 32 for the insulating ring are formed by using the patterns 22b and 24, respectively. At this time, as shown in FIGS. 21A and 21C, in a region in which the trench 32 for the insulating ring is to be formed, the silicon oxide film 20 and silicon semiconductor substrate 17 are etched using the pattern 24, to form the trench 32 for the insulating ring. In contrast, as shown in FIGS. 21B and 21D, in a region in which the trenches 25 for the alignment mark is to be formed, the photoresist film 21a, silicon oxide film 20 and silicon semiconductor substrate 17 are etched using the pattern 22b, to form the trenches 25 for the alignment mark. As described above, in a region in which the trenches 25 for the alignment mark are to be formed, the photoresist film 21a is additionally provided. Therefore, in this region, the time to begin to etch the silicon semiconductor substrate 17 becomes later by time for etching the photoresist film 21 a to expose the silicon semiconductor substrate 17, as compared to a region in which the trench 32 for the insulating ring is to be formed. As a result, even the trenches 25 for the alignment mark and the trench 32 for the insulating ring are formed in one etching process, the trench 32 for the insulating ring becomes deeper than the trenches 25 for the alignment mark.

After that, the semiconductor device according to the present exemplary embodiment is completed by performing the processes of FIGS. 11 to 18 of the first exemplary embodiment. In the present exemplary embodiment, it is possible to form the trenches 25 for the alignment mark and the trench 32 for the insulating ring in one etching process, thereby reducing the production cost. In addition, by adjusting the film thickness of the photoresist film 21a, it is possible to control the time to etch the photoresist film 21a and then to expose the silicon semiconductor substrate 17. As a result, the trenches 25 for the alignment mark can be controlled so that they have a desired depth. That is, since the time to etch the photoresist film 21a becomes longer by thickening the photoresist film 21a, the shallow trenches 25 can be formed. On the other hand, since the time to etch the photoresist film 21a becomes shorter by thinning the photoresist film 21a, the deep trenches 25 can be formed. In the both cases described above, the trench 32 for the insulating ring becomes deeper than the trenches 25 for the alignment mark.

In the above exemplary embodiment, the negative photoresist film 21a is used as a first film, and the positive photoresist film 21b is used as a second film. This is because that the photoresist film 21 a needs to remain at the time of developing the photoresist film 21b. As long as the first film remains stably at the time of applying lithography technology for forming the third pattern, material of the first film is not limited to the negative photoresist, and but may be any material. In addition, as long as the second film has the etching selectivity to the first film, silicon oxide film 20, and silicon semiconductor substrate 17 at the time of etching, material of the second film is not limited to the positive photoresist, and but may be any material. For example, the positive photoresist film may be used as a first film, and the negative photoresist film may be used as a second film. Alternatively, the polysilicon film or amorphous carbon (a-C) film may be formed as a first film, and the silicon oxide film or silicon nitride film may be used as a second film.

Examples of the semiconductor devise include wafer and chip.

It is apparent that the present invention is not limited to the above embodiments, but may be modified and changed without departing from the scope and spirit of the invention.

What is claimed is:

1. A semiconductor device, comprising:
a semiconductor substrate;
a through silicon via penetrating through the semiconductor substrate in a thickness direction thereof;
a first insulating region made of an insulating material buried in a first trench, the first trench surrounding the through silicon via and penetrating through the semiconductor substrate from a first principal surface thereof to a second principal surface thereof;
a second insulating region formed below the first principal surface of the semiconductor substrate; and
an isolation region made of an insulating material buried in a second trench formed below the first principal surface of the semiconductor substrate,
wherein the second insulating region is deeper than the second trench and shallower than the first trench.

2. The semiconductor device according to claim 1,
wherein a bottom surface of the second insulating region is positioned closer to the first principal surface than to the second principal surface.

3. The semiconductor device according to claim 1,
wherein the second insulating region has a trench shape.

4. The semiconductor device according to claim 1,
wherein the second insulating region is disposed in a scribe region.

5. The semiconductor device according to claim 1,
wherein the second insulating region is an alignment mark.

6. The semiconductor device according to claim 5,
wherein the alignment mark has a line-and-space shape when viewed in a direction toward the first principal surface.

7. The semiconductor device according to claim 6,
wherein the alignment mark includes a plurality of marks,
each mark has a width ranging from 1 to 3 μm and a length ranging from 30 to 50 μm, and
an interval between marks ranges from 2 to 6 μm.

8. The semiconductor device according to claim 1,
wherein the first insulating region is an insulating ring.

9. The semiconductor device according to claim 8,
wherein the insulating ring has an annular shape having a depth ranging from 30 to 50 μm measured from the first principal surface of the semiconductor substrate and a diameter ranging from 15 to 30 μm.

10. The semiconductor device according to claim 1,
wherein the insulating material buried in the first trench is none-doped silicate glass.

11. The semiconductor device according to claim 1,
wherein the second insulating region contains none-doped silicate glass.

12. The semiconductor device according to claim 1,
wherein the second insulating region has a depth of 2 μm or smaller measured from the first principal surface of the semiconductor substrate.

13. The semiconductor device according to claim 1,
wherein the second insulating region has a depth of 0.1 μm or greater measured from the first principal surface of the semiconductor substrate.

14. A method for manufacturing a semiconductor device, comprising:
forming a first trench surrounding a part of a semiconductor substrate and a trench for a second insulating region, below a first principal surface of the semiconductor substrate;
burying an insulating material in the first trench and the trench for the second insulating region, to form a first insulating region and the second insulating region, respectively;
forming a photoresist film on the first principal surface of the semiconductor substrate, after burying the insulating material;
transferring a first pattern aligned with reference to the second insulating region to the photoresist film;
etching the semiconductor substrate using the photoresist film as a mask to form a second trench, after transferring the first pattern to the photoresist film;
burying an insulating material in the second trench, to form an isolation region;
grinding a second principal surface of the semiconductor substrate until the first insulating region is exposed; and
forming a through silicon via penetrating through the part of the semiconductor substrate surrounded by the first trench from the first principal surface thereof to the second principal surface thereof,
wherein the second insulating region is deeper than the second trench and shallower than the first trench.

15. The method for manufacturing a semiconductor device according to claim 14, further comprising:
forming a protective film on the first principal surface of the semiconductor substrate,
wherein the forming the first trench and the trench for the second insulating region comprises:
patterning the protective film, to form a first protective pattern;
etching the semiconductor substrate using the first protective pattern as a mask, to form the trench for the second insulating region;
patterning the protective film, to form a second protective pattern; and
etching the semiconductor substrate using the second protective pattern as a mask, to form the first trench, and
wherein the trench for the second insulating region is formed before the first trench is formed.

16. The method for manufacturing a semiconductor device according to claim 14,
wherein the forming the first trench and the trench for the second insulating region comprises:
forming a second pattern made of a first film and positioned on a region in which the trench for the second insulating region is to be formed;
forming a third pattern made of a second film on the second pattern; and
etching the first film and the semiconductor substrate using the third pattern, to form the first trench and the trench for the second insulating region.

17. The method for manufacturing a semiconductor device according to claim 16,
wherein the first film is made of one of a negative photoresist film and a positive photoresist film, and
the second film is made of the other of the negative photoresist film and the positive photoresist film.

18. The method for manufacturing a semiconductor device according to claim 14,
wherein the first insulating region is an insulating ring.

19. The method for manufacturing a semiconductor device according to claim 14,
wherein the second insulating region is an alignment mark.

20. The method for manufacturing a semiconductor device according to claim 19,
wherein the alignment mark has a line-and-space shape when viewed in a direction toward the first principal surface.
